(19) United States
(12) Patent Application Publication
(10) Pub. No.: US 2010/0035495 A1
(43) Pub. Date: Feb. 11, 2010

(54) FLAME RETARDANT PRODUCTS

(76) Inventor: Hubertus Marie Christine H.M.C. Stijnen, Stein (NL)

Correspondence Address: NIXON & VANDERHYE, PC, 901 NORTH GLEBE ROAD, 11TH FLOOR, ARLINGTON, VA, 22203, US

(21) Appl. No.: 12/307,653

(22) PCT Filed: Jul. 3, 2007
(86) PCT No.: PCT/EP2007/005865

§ 371 Date: Aug. 11, 2009

(30) Foreign Application Priority Data
Jul. 7, 2006 (EP) 06014116.5

(51) Int. Cl. C09K 21/10; C23C 16/00; B32B 5/00; B32B 27/34; B32B 27/36; B32B 27/00; B32B 21/04

(52) U.S. Cl. 442/147; 252/601; 427/255.6; 428/318.4; 428/337; 428/341; 428/474.4; 428/480; 428/500; 428/532; 428/537.1; 544/180

(57) ABSTRACT

The invention relates to a flame retardant product comprising a one or two dimensional substrate further comprising a crystalline triazine layer. The amount of trazine is such that the flame retardant properties of the substrate are improved and preferably the amount is about 0.1 g/m2 or higher, and about 500 g/m2 or lower. The triazine is preferably vapor deposited, and is preferably melamine.

The invention relates to certain flame retardant products, in particular flame retardant one and two dimensional products like fibers, films, fabrics, sheets or layers.

A number of ways are known to enhance the flame retardant properties of products like textile, natural or synthetic fibers, wood panels, synthetic or natural leather, protective or insulating sheets like foamed materials, electronic panels, wires and cables. It is for example known to incorporate, paint or impregnate the products with chlorinated or brominated chemicals. It is also known to use aluminatrihydrate or polyphosphates as flame retardant additives during preparation, or as later applied intumescing coating. The use of brominated or chlorinated chemicals is subject of environmental concerns, so these chemicals are preferably not used. Other methods to achieve flame retardant properties are not always satisfactory, and alternative and better ways to achieve useful flame retardant properties is searched for.

The inventors have found a way to achieve flame retardant properties, which allows for a simple process, while achieving good properties.

One object of the invention is to provide one or two dimensional products with improved flame retardant properties.

Another object of the invention is to provide a process to make one or two dimensional products with improved flame retardant properties.

These objects and other advantageous features are achieved with the present invention, wherein the product comprises a one or two dimensional substrate further comprising a crystalline triazine layer, wherein the amount of triazine in said layer is such, that a flame retardant property of the substrate is improved.

These objects and other advantageous features are furthermore achieved with a process, whereby a one or two dimensional substrate is subjected to vapor deposition of triazine, to obtain a vapor-deposited crystalline triazine layer wherein the amount of triazine is such, that a flame retardant property of the substrate is improved.

These objects and other advantageous features are furthermore achieved by the use of a crystalline triazine layer a as a flame retardant covering on a product.

In one embodiment of the invention, the amount of triazine on the substrate is about 0.1 g/m² or higher, and about 500 g/m² or lower.

In another embodiment of the invention, the surface of the one or two dimensional substrate comprises a crystalline melamine layer of 50 nm or more.

Suitable triazines for vapor deposition include, but are not limited to, melamine, melam, melem, acetoguanamine, benzoguanamine, dicyanediamine, toluenesulphonamide, urea and thiourea. Preferred examples are melamine and urea, because of cost reasons. In one embodiment, it is preferred to use melamine as the triazine for vapor deposition, as that is a widely available material and gives very good characteristics.

In one embodiment of the invention, a mixture of triazines is used for vapor deposition. In another embodiment of the invention, two or more triazines are vapor deposited consecutively, from different vapor deposition vessels. This may be advantageous over the use of mixtures, as far as the sublimation temperature varies for the different triazines.

In one embodiment of the invention, both sides of the substrate have a layer of crystalline triazine.

In another embodiment, one or more flame retardant or intumescing compounds other than the triazine are also deposited on the one or two dimensional substrate. Preferred other compounds are those that can be vapor deposited. Suitable examples of other flame retardant compounds include but are not limited to melamine cyanurate, melamine (poly)phosphates, melamine borate, phosphorus, phosphate esters, inorganic salts, siloxane, silicate, aluminum trihydrate, antimony complex and zinc/magnesium complex.

In a preferred embodiment, the substrate has at least one layer of crystalline triazine, the layer consisting of about 90% by wt or more of the crystalline triazine. Preferably, about 97% or more of the layer consists of crystalline triazine The substrate preferably has a one or two dimensionally elongated form. Suitable examples of such substrates include, but are not limited to, fibers, films, sheet or layers.

One dimensional forms are used in this application to denote products that are relatively small in 2 dimensions, in comparison to the third dimension. Suitable examples of one-dimensional forms include synthetic or natural fibers and ropes. Suitable examples of fibers include, but are not limited to, carbon fibers, polyamide, polyester, polyacrylic, polyacrylamide and polyolefin fiber, or cotton, wool, or silk fibers. The one dimensional products may have a diameter or thickness of a few pm to several cm.

Two dimensional forms are used in this application to denote products that are relatively small in one dimension, in comparison to the other two dimensions. Suitable examples of two dimensional forms include but are not limited to sheet, fabric, films and layers. Suitable examples of two dimensional forms include sheets from natural or synthetic leather, wood, fabric from the above mentioned fibers, plastic or resin protective or insulating sheets, films and the like. The two dimensional form generally will have a thickness of a few pm to several cm.

In one embodiment, it is preferred to use a two dimensional form.

In one embodiment, the two dimensional product has a thickness of about 1 mm or more, preferably, about 2 mm or more. Generally, the thickness will be about 10 cm or less, preferably about 5 cm or less.

In one embodiment of the invention, the two dimensional product is porous. Porous means in this description that air or moisture can diffuse through the two-dimensional products without applying substantial pressure. Porous products for example are fabrics and open-cell foams.

In another embodiment, the two dimensional product has a heterogeneous structure, like a closed-cell foam.

In one embodiment, the two dimensional form is a fabric from synthetic or natural fiber.

In another embodiment, the two dimensional form is a wood panel.

In another embodiment, the two dimensional form is synthetic or natural leather.

In another embodiment, the two dimensional form is a protective or insulating sheets. Suitable insulating sheets include, but are not limited to foamed sheets. Foams may be based on natural or synthetic materials. Suitable examples of such materials include natural latex, natural rubber, polypropylene, copolymers of polyethylene and polypropylene, polystyrene, polyether, polybutadiene, polyurethane or the like.

In another embodiment of the invention, the substrate is colored, which is achieved by vapor deposition of at least one organic dye, together with the triazine deposition, or in a vapor deposition chamber next to (before or after) the triazine vapor deposition chamber.

The amount of triazine on the substrate is generally about 0.1 g/m² or more, and preferably about 1 g/m² or more, and more preferably about 5 g/m² or more. It is more preferred to use about 10 g/ m² or more, and most preferred to use 11 g/m² or more. A useful amount will depend on the substrate. For example a loose fabric may need much less melamine to have flame retardant properties than a thick fabric or a wood panel. Hence, small amounts of triazine like for example about 0.5 g/m² or about 2 g/m² or more may be advantageous because an increase in flame retardant properties may be observed.

The amount of triazine on the substrate is generally about 500 g/m² or less, preferably about 100 g/m² or less. An amount of about 50 g/ m² or less is most preferred. Higher amounts may cause difficulties with processing the triazine comprising substrate and increase the price.

In one embodiment of the invention, the preferred thickness of the triazine layer is about 100 nm or more, more preferably, about 200 nm or more. The maximum thickness of the layer is not critical, and may be 1000 μm or less, preferably 100 μm or less, and for example 50 μm or less or 20 μm or less.

The triazine layer preferably is substantially continuous on the surface of the substrate, which means that little void space is detectable between the triazine crystals. For example, the void space may be about 20% or less, preferably 10% or less, and even more preferred about 5% or less. In the most preferred embodiment, the void space is about 0%.

In one embodiment of the invention, the vapor deposition of triazine on the substrate can be performed as described in U.S. Pat. No. 6,632,519, WO 2004/101662 and WO 2004/101843, which disclosures are herewith incorporated by reference. The vapor deposition preferably is carried out in a vacuum chamber, at reduced pressure. Preferably, the deposition is performed in an inert atmosphere, like for example a nitrogen atmosphere. Preferably, the vapor deposition process takes place in a vacuum chamber having a pressure of about 10 mBar or less, preferably of about 1 mBar or less, and more preferably of about 10⁻³ mBar or less. A low pressure has the advantage that the triazine evaporates at a lower temperature, so less heating is necessary.

In another embodiment of the invention, the vapor deposition of triazine is performed at atmospheric pressure. This is in particular advantageous when a substrate is used with air entrapped, with a high moisture content or the like. Suitable examples include closed cell foams, foams with a high residual moisture content, porous wood and the like.

In general, the triazine will be heated. The required temperature for sublimation is dependent on the vacuum (if applied), and is preferably about 150° C. or higher, preferably about 200° C. or higher, even more preferred for for example melamine at a temperature between about 250° C. and 300° C. Without vacuum, the temperature for for example melamine would be between 300° C. and 360° C. Generally, the temperature to heat the triazine will be close to the decomposition temperature, which is different for each triazin. For melamine, the temperature will be about 350° C. or lower. For melam, the temperature will be about 450° C. or lower.

Generally, to achieve a reliable vapor deposition of the triazine, it is preferred to keep the substrate at a temperature that is about 100° C. lower than the temperature for heating the triazine, preferably, the temperature difference is about 200° C. or more, and even more preferred, about 300° C. or more. Preferably, the substrate is kept at about room temperature, e.g. at a temperature of about 20° C. Some heating will occur during the deposition step, but this is not critical. The amount of triazine deposited can be steered by the amount of time the substrate is subjected to the vapor deposition, the concentration of the triazine in the vapor (which is dependent a.o. on the temperature the triazine is heated and the pressure).

In one embodiment of the present invention, the speed of the substrate over the vacuum chamber is about 0.5 m/s or more. The speed generally will be about 10 m/s or less. The temperature of the triazine in the vacuum chamber has a temperature of about 250° C. or higher, preferably about 330° C. or higher. The vacuum is preferably about 10 Pa or less.

It is possible to perform the vapor deposition during up to a few minutes, but this generally will not be economically attractive. An advantage of high speed, high vacuum, high vapor concentration deposition, with a temperature difference of triazine and the substrate of about 250° C. or more is, that triazine is deposited as a very microcrystalline layer, which improves the flame retardant properties.

In one embodiment of the invention, the triazine on the substrate has a microcrystalline structure. On a SEM photograph, the crystal size of melamine preferably shows as multi crystalline platelets. The platelets generally will have a width of about 1000 μm or less, more preferably about 500 μm or less. Generally, the width will be about 200 nm or more, preferably about 500 nm or more. Generally, the thickness of the platelets will be about 100 μm or less, preferably about 50 μm or less. Generally, the thickness will be about 1 nm or more, preferably about 5 nm or more.

In one embodiment, the substrate is a so-called continuous substrate, which may be in the form of a role of the one or two dimensional substrate. The substrate is drawn through a chamber for vapor deposition, which chamber may be at atmospheric or sub-atmospheric pressure. The substrate generally will be for example about 50 m long or more, preferably about 200 m or more. Generally, the length will be about 20 km or less, or about 10 km or less. Generally, if two-dimensional, the substrate will have a width of 50 cm or more, preferably 1 m or more. Generally, the width will be about 8 m or less, or 6 m or less.

In another embodiment, the substrate is a two dimensional form, such as a sheet-like object. The size of a sheet or layer is not critical, and may be determined by practical considerations. Sheets or layers may have a size of about 10 cm² or larger, for example about 40 cm². Sheets or layers will generally have a size of about 10 m² or lower, preferably 2 m² or lower.

The product comprising the substrate and the crystalline triazine layer has improved flame retardant properties when compared to the substrate without the crystalline triazine layer.

In a further embodiment of the invention, the product with the crystalline triazine layer is coated with a coating to protect the crystalline triazine layer. Such coating may be e.g. a lacker, UV-curable coating, heat-curable coating or the like. The use of a protective coating is in particular an advantage if the product is to be used where it may become wet, as the crystalline triazine generally is (somewhat) water soluble. And—even though the crystalline triazine layer is scratch resistant—thewear resistance may be limited. It is preferred to use organic solvent based coatings or 100% solids coatings. In case the coatings is heat-curable, heating can be up to 250° C., depending on the substrate. Suitable coatings are for example can-coatings, industrial wood coatings and the like. Generally, the coatings contains polyester, alkyd, urethane, acrylic or other binder polymers. Further, the coatings generally comprise crosslinking compounds such as epoxydes, blocked isocyanates, ethylenically unsaturated groups, etherified methylol-melamine resin and the like.

In a further preferred embodiment of the invention, the further coating exhibits itself also flame retardant properties, because it comprises e.g. flame retardant additives.

Flame retardant properties are composed of a number of factors, and many test methods are available. Generally, the test method applied depends on the use of the product. Suitable test methods include, but are not limited to, ASTM E 119 on building construction and materials, NFPA 130 on fixed guideway transit systems, UL 1717 for internal finish material, UBC 26-3 for interior foam plastic finishes, ASTM D-1230 for fabrics, and TB 117 or BS 5852 for materials in upholstered furniture.

A number of characteristics can be analyzed when testing flame retardant properties: These characteristics include, but are not limited to, time to ignition, afterflame, afterglow, dripping, char length, flame spread, self-extinguishing time, mass loss due to burning and smoldering.

The use of a crystalline triazine layer for example may reduce the time to ignition, and the time the flame stays visible (hence, it increases the ability to self-extinguish). The char length may be shortened and the mass-loss lowered. Preferably, the amount of melamine is such, that an improvement in one of a flame retardant criterion is observed by—on average—about 10% or more, preferably with about 30% or more. Generally, 5 or 10 test specimen are tested. It is even more preferred to use an amount of melamine, optionally together with other flame retardants, such that the required classification is met.

For synthetic products, one of UL 94 and UL 746A are in particularly preferred as relevant test method. UL 94 focuses on flame spread or extinguishing properties, whereas UL 746A focuses on resistance to ignition and surface tracking. More in particular, a standard test for measuring flammability and/or combustibility is known as Underwriters Laboratories UL94, “Test for Flammability of Plastic Materials—UL-94” (Jul. 29, 1997), the disclosure of which is hereby expressly incorporated herein by reference.

In one preferred embodiment of the invention, the product comprises such an amount of crystalline triazine on the substrate—optionally together with other flame retardant compounds—that the product conforms with a V1 requirement according to UL94, more preferably with a V0 requirement. In another preferred embodiment of the invention,—in particular if the substrate is a low density foam—the product comprises such an amount of crystalline triazine—optionally together with other flame retardant compounds—that the product conforms with a HF2 requirement according to UL94, more preferably with a HF1 requirement. In yet another embodiment of the invention—in particular for not self-supporting substrates such as fabrics or films—the product comprises such an amount of crystalline triazine—optionally together with other flame retardant compounds—that the product conforms with a VTM-1 requirement according to UL94, more preferably with a VTM-0 requirement. In yet another preferred embodiment, the product comprises such an amount of crystalline triazine on the substrate—optionally together with other flame retardant compounds—that the product conforms with one or more requirement according to UL 746A.

Particularly desirable products in accordance with this invention should reach a V-0 classification, although for certain applications a classification at a lower level (such as V-1), depending on the end use for which the material is intended may be sufficient. Details of this test and the performance of products within the scope of the invention under test conditions are provided below.

UL94 specimens for 20 mm Vertical Burning Test are prepared as a tensile bar. The specimens are typically 125 mm in length and 13 mm in width, and 3.2 mm, 1.6mm, or 0.8 mm in thickness. The surface of such a substrate is subsequently subjected to vapor deposition of melamine. The vertical burning test to classify materials as V-0, V-1 or V-2 is run at least one day after preparation of the bar specimen and in accordance with UL94 which is hereby incorporated in its entirety by reference, except that no provision has to be made for controlling the room temperature and humidity and the bars need not to be equilibrated for 2 days.

Thickness of the test specimens may also be important for the interpretation of the test results. It is more difficult to pass the UL94 vertical burning test for a thinner specimen than for a thicker one; however, that will also depend on the relative amount and thickness of the crystalline melamine layer.

Flame retardant products like flame retardant foams and fabrics preferably are used in transport (planes, automotive, trains and the like), building (hospitals, schools, houses, hotels, restaurants and the like), electronics (housing for electrical equipment) and the like.

The invention will be further elucidated by the following examples, without being limited thereto.

### EXAMPLES

### Examples 1-3

### Vapor Deposition of Melamine on a Fabric of Nylon-6 (Polyamide)

Polyamide fabric of 80 g/m² (20 times 30 cm) is put in a vacuum chamber. The vacuum chamber comprised a small oven with melamine. The melamine is heated to 305° C. while the pressure is kept at 10⁻⁵ mBar. During a certain time, melamine is deposited, as shown in table 1.

TABLE 1

| Example | Time side 1 | Time side 2 | Total melamine | Amount per m² | |
|---|---|---|---|---|---|
| 1 | 10 min | — | 2.5 g | 37 | g |
| 2 | 3 min | — | 0.98 g | 15.6 | g |
| 3 | 4 min | 4 min | 2.1 g | 31 | g |

### Examples 4-5

### Vapor Deposition of Melamine on a Wood Panel

A wood panel of 650 g/m² (20 times 30 cm) is put in a vacuum chamber. The vacuum chamber comprised a small oven with melamine. The melamine is heated to 305° C. while the pressure is kept at 10⁻⁵ mBar. During a certain time, melamine is deposited, as shown in table 2.

TABLE 2

| Example | Time side 1 | Time side 2 | Total melamine | Amount per m² |
|---|---|---|---|---|
| 4 | 3 min | — | 1.0 g | 15 g |
| 5 | 4 min | 4 min | 2.3 g | 33 g |

The examples show that melamine is successfully vapor deposited on these substrate; both on one side and on two sides, in amounts substantially larger than generally used in the process according to U.S. Pat. No. 6,632,519. It should also be noted, that these experiments are performed on laboratory equipment. On industrial scale, one can easily obtain high speeds (several seconds or less per meter) vapor deposition that would yield amounts as shown in this table.

Furthermore, the products comprising the crystalline triazine layer exhibit improved flame retardant properties such as enhancing the time to ignition and lowering the flame time.

### Example 6-10

### And Comparative Experiments A-C; Vaport Deposition of Melamine on PUR Foam

From a 1 cm thick polyurethane (PUR) sheet of foam, 7×7 cm pieces were cut. An amount of melamine was deposited. The melamine deposited pieces were subjected to a flame test, by keeping a flame for 5 sec under the piece, and determining flame retardant properties. Results are given in Table 3

TABLE 3

| | Amount of | |
|---|---|---|
| experiment | melamine (g/m²) | Flame retardant behavior |
| A | None | Broad flame, no immediate extinction |
| B | 1.2 | Broad flame, no immediate extinction |
| C | 1.4 | Broad flame, no immediate extinction |
| 6 | 5.8 | Broad flame, immediate extinction |
| 7 | 9.0 | Smaller flame, immediate extinction |
| 8 | 16.6 | Narrow flame, immediate extinction |
| 9 | 17.6 | Narrow flame, immediate extinction |
| 10 | 26.7 | Narrow flame, immediate extinction |

As appears from these experiments, on this substrate, a small amount of melamine does not give an improvement in flame retardant properties, whereas higher amounts are very effective.

1. Product comprising a one or two dimensional substrate further comprising a crystalline triazine layer in an amount such that the flame retardant properties of the product are improved.

2. Product comprising a one or two dimensional substrate further comprising a crystalline triazine layer wherein the amount of triazine is about 0.1 g/m² or higher, and about 500 g/m² or lower

3. Product according to claim 1 wherein the amount of triazine is about 5 g/m² or higher.

4. Product according to claim 1 wherein the triazine is melamine.

5. Product according to claim 1 wherein the substrate is porous.

6. Product according to claim 1 wherein the substrate is heterogeneous.

7. Product according to claim 1 wherein the substrate has a thickness of about 1 mm or more

8. Product according to claim 1, wherein the substrate comprises synthetic or natural fiber.

9. Product according to claim 1 wherein the substrate comprises carbon fibers, polyamide, polyester, polyacrylic, polyacrylamide and polyolefin fiber, or cotton, wool, or silk fibers

10. Product according to claim 1 wherein the substrate comprises films, fabric, sheet or layers.

11. Product according to claim 1 wherein the substrate comprises natural or synthetic leather, wood panel, fabric, protective or insulating sheets.

12. Product according to claim 1 wherein the substrate is a foamed sheet of synthetic material.

13. Product according to claim 12, wherein the substrate is polyurethane foam.

14. Product according to claim 1, wherein the triazine is microcrystalline, having a platelet structure with a width of about 500 μm or less.

15. Product according to claim 1, wherein the product with crystalline triazine layer further comprises a protective coating on the triazine layer.

16. Use of a crystalline triazine layer a as a flame retardant covering on a product.

17. Process for making a flame retardant product by subjecting a one or two dimensional substrate to vapor deposition of triazine, to obtain a vapor-deposited crystalline triazine layer on the substrate.
